(19) United States
(12) Patent Application Publication
(10) Pub. No.: US 2023/0166280 A1
(43) Pub. Date: Jun. 1, 2023

(54) FLUID SPRAY DEVICE FOR PROCESSING SUBSTRATE

(71) Applicant: ZEUS CO., LTD., Hwaseong-si (KR)

(72) Inventors: Ji Ho PARK, Hwaseong-si (KR); Ji Hoon SONG, Cheonan-si (KR); Young Hoon KANG, Anyang-si (KR); Hyung Jin KIM, Ansan-si (KR)

(73) Assignee: ZEUS CO., LTD., Hwaseong-si (KR)

(21) Appl. No.: 17/868,093

(22) Filed: Jul. 19, 2022

(30) Foreign Application Priority Data
Dec. 1, 2021 (KR) 10-2021-0169684

(51) Int. Cl. B05B 12/36; B05B 12/18

(52) U.S. Cl. CPC B05B 12/36; B05B 12/18; H01L 21/67051

(57) ABSTRACT

A fluid spray device for processing a substrate according to the present invention includes a spray nozzle configured to spray a processing fluid toward a substrate supported on a table, and a scattering prevention cover configured to block contaminants from being scattered by the sprayed processing fluid hitting the substrate.

### CROSS-REFERENCE TO RELATED APPLICATION

This application claims priority to and the benefit of Korean Patent Application No. 10-2021-0169684, filed on Dec. 1, 2021, the disclosure of which is incorporated herein by reference in its entirety.

### BACKGROUND

### 1. Field of the Invention

The present invention relates to a fluid spray device for processing a substrate, and more particularly, to a fluid spray device for processing a substrate, which is capable of preventing scattering of contaminants caused when a processing fluid is sprayed in order for removing foreign materials attached to a substrate.

### 2. Discussion of Related Art

In general, in a semiconductor process, an etching process of etching substrates, that is, wafers, a singulation process of sawing the wafers into a plurality of dies, and a cleaning process of cleaning the wafers are performed. A substrate processing apparatus is used in the wafer etching process or the cleaning process

The substrate processing apparatus includes a rotary table on which a wafer is rotatably mounted and supported, and a fluid spray device for processing a substrate which sprays a processing fluid onto the wafer mounted on the rotary table. The fluid spray device for processing a substrate sprays the processing fluid onto the wafer while the wafer mounted on the rotary table rotates. For this reason, foreign materials (particles) attached to the wafer can be mixed with the processing fluid and randomly scattered around the wafer. The foreign materials mixed with the processing fluid and scattered can contaminate a chamber of the substrate processing apparatus and the fluid spray device for processing a substrate and can cause malfunction or failure in severe cases. In order to prevent such problems, since the chamber of the substrate processing apparatus and the fluid spray device for processing a substrate should be frequently cleaned, the productivity of a wafer processing operation decreases and costs increase.

A background technique of the present invention is disclosed in Korean Patent Publication No. 10-2014-0113511 (published on Sep. 24, 2014, and titled “substrate processing apparatus and wafer processing method”).

### SUMMARY OF THE INVENTION

The present invention is directed to providing a fluid spray device for processing a substrate which includes a scattering prevention cover configured to block scattering of contaminants, in which a processing fluid and foreign materials are mixed, without rotation, and is configured to prevent contaminants from being attached to the scattering prevention cover.

According to an aspect of the present invention, there is provided a fluid spray device for processing a substrate including a spray nozzle configured to spray a processing fluid toward a substrate supported on a table, and a scattering prevention cover configured to block contaminants from being scattered by the sprayed processing fluid hitting the substrate.

The scattering prevention cover may include an inner wall disposed to face the spray nozzle, and an outer wall disposed further apart from the spray nozzle than the inner wall.

The scattering prevention cover may have a cover inner space which is formed to allow gas to flow between the inner wall and the outer wall.

The fluid spray device may further include a gas supply unit configured to supply a gas with high pressure higher than atmospheric pressure to the cover inner space, wherein the gas with high pressure passes through the inner wall to be discharged outward from the cover inner space.

A plurality of ventilation holes may be formed in the inner wall.

The inner wall may be made of a porous material in which a plurality of micropores are formed.

The fluid spray device may further include a gas supply unit configured to supply a gas with high pressure higher than atmospheric pressure to the cover inner space, wherein the scattering prevention cover further includes a lower wall configured to connect a lower end of the inner wall and a lower end of the outer wall.

The gas with high pressure supplied to the cover inner space through the gas supply unit may pass through the lower wall to be discharged outward from the cover inner space.

A plurality of ventilation holes may be formed in the outer wall.

The outer wall may be made of a porous material in which a plurality of micropores are formed.

The fluid spray device may further include a gas supply unit configured to supply a gas with high pressure higher than atmospheric pressure to the cover inner space, wherein the scattering prevention cover further includes a first upper wall connected to an upper end of the inner wall and a second upper wall connected to an upper end of the outer wall, and the cover inner space extends to allow gas to flow between the first upper wall and the second upper wall.

The gas with high pressure supplied to the cover inner space through the gas supply unit may pass through the first upper wall to be discharged outward from the cover inner space.

A plurality of ventilation holes may be formed in the first upper wall.

The first upper wall may be made of a porous material in which a plurality of micropores are formed.

A lower end of the scattering prevention cover may be closer to an upper surface of the substrate than a lower end of the spray nozzle, and when the processing fluid is sprayed onto the substrate from the spray nozzle, a separation distance between the lower end of the scattering prevention cover and the upper surface of the substrate may be in a range of 0.5 mm to 100 mm.

### BRIEF DESCRIPTION OF THE DRAWINGS

FIG. 1 is a perspective view illustrating a substrate processing apparatus including a fluid spray device for processing a substrate according to one embodiment of the present invention.

FIG. 2 is a longitudinal cross-sectional view of the fluid spray device for processing a substrate of FIG. 1.

FIG. 3 is a partially cutaway perspective view illustrating a portion of a scattering prevention cover according to a modified example replacing a scattering prevention cover of FIG. 3.

### DETAILED DESCRIPTION OF EXEMPLARY EMBODIMENTS

Hereinafter, a fluid spray device for processing a substrate according to embodiments of the present invention will be described in detail with reference to the accompanying drawings. Terminologies used herein are defined to appropriately describe the exemplary embodiments of the present invention and thus may be changed according to the intent of a user or an operator, or a custom in the field to which the present invention pertains. Accordingly, the terminologies should be defined based on the following overall description of the present specification.

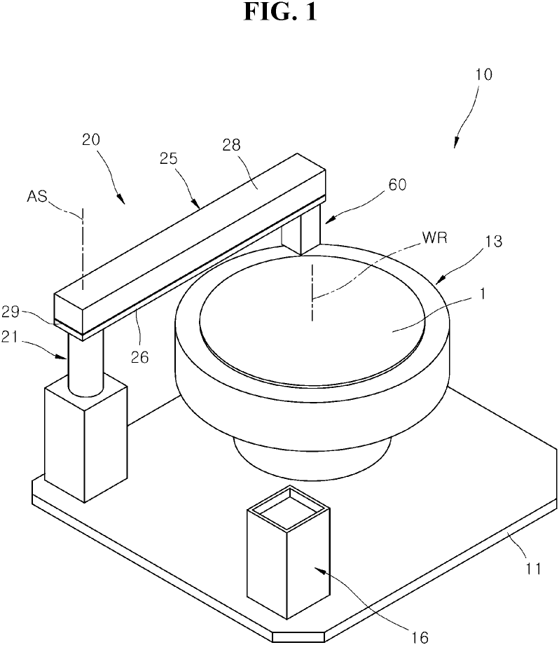

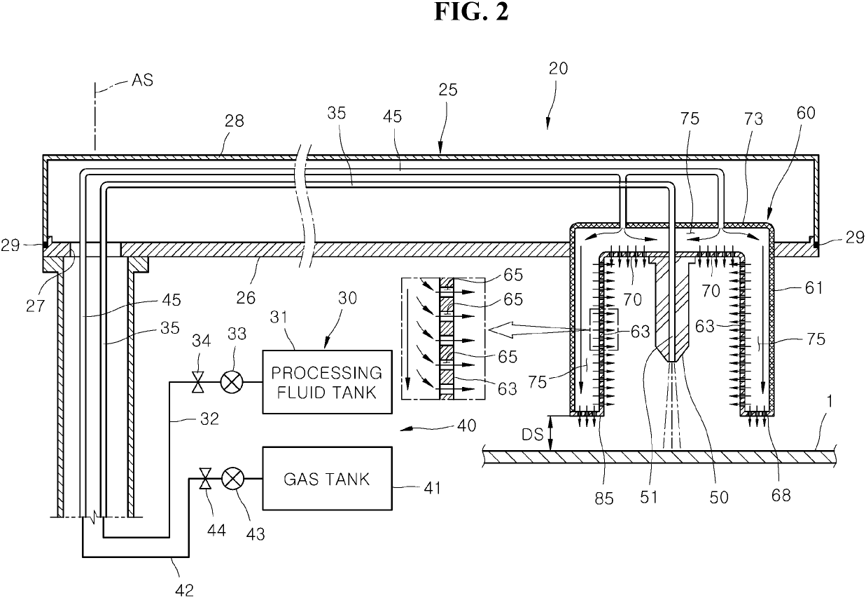

FIG. 1 is a perspective view illustrating a substrate processing apparatus including a fluid spray device for processing a substrate according to one embodiment of the present invention, and FIG. 2 is a longitudinal cross-sectional view of the fluid spray device for processing a substrate of FIG. 1. Referring to FIGS. 1 and 2 together, a fluid spray device 20 for processing a substrate according to one embodiment of the present invention is provided in a substrate processing apparatus 10 which sprays a processing fluid onto an upper surface of a substrate 1 to process the substrate 1. Although the substrate 1 shown in FIG. 1 is a wafer used for manufacturing semiconductor chips, the present invention is not limited to the wafer, and for example, the substrate which is subject to the present invention may be a substrate for a flat panel display, a substrate for a solar panel, or the like.

The substrate processing apparatus 10 includes a base 11, a table 13 supported on the base 11, the fluid spray device 20 for processing a substrate, and a cover holder 16. During a process in which, while the table 13 supports the substrate 1, the table 13 rotates about a table axis WR vertically extending and sprays the processing fluid to process the substrate 1, the table 13 rotates the substrate 1. Although not clearly shown, the table 13 may be a chuck table including a chuck for fixing the substrate 1.

The fluid spray device 20 for processing a substrate includes a swing arm 25, a swing arm support post 21, a spray nozzle 50, a scattering prevention cover 60, a processing fluid supply unit 30, and a gas supply unit 40. The swing arm support post 21 is fixedly supported on the base 11 at a point spaced apart from the chuck table 13 and extends upward. The swing arm 25 horizontally extends, one end portion thereof is rotatably coupled to the swing arm support post 21, and the other end portion thereof is fixedly supports the scattering prevention cover 60. The swing arm 25 pivots about an arm axis AS extending in a length direction of the swing arm support post 21. In FIG. 1, a swing arm rotation driving unit for rotationally driving the swing arm 25 about the arm axis AS is omitted.

The swing arm 25 may include first and second arm housing members 26 and 28 which are coupled with an inner space formed therebetween. One end portion of the first arm housing member 26 is coupled to and supported on an upper end of the swing arm support post 21. An inner space extending in the length direction of the swing arm support post 21 may be formed inside the swing arm support post 21. A connection through-hole 27 may be formed in one end portion of the first arm housing member 26 such that the inner space of the swing arm 25 communicates with the inner space of the swing arm support post 21. The scattering prevention cover 60 is fixedly coupled to the other end portion of the first arm housing member 26.

The second arm housing member 28 is coupled to an outer peripheral edge of the first arm housing member 26 to form the inner space of the swing arm 25. In order to prevent contaminants from permeating into the swing arm 25 during a substrate processing process of spraying a fluid to process the substrate 1, the first arm housing member 26 and the second arm housing member 28 are coupled with a sealing member 29, which is made of a rubber material, interposed therebetween. The sealing member 29 may be an O-ring or a gasket.

When the swing arm 25 rotates about the arm axis AS so that the spray nozzle 50 is positioned above the substrate 1, the spray nozzle 50 sprays the processing fluid onto an upper surface of the substrate 1. The spray nozzle 50 may be fixedly supported on an upper end portion of the scattering prevention cover 60 fixedly supported by the swing arm 25. The processing fluid supply unit 30 supplies the processing fluid to the spray nozzle 50. The processing fluid supply unit 30 may include a processing fluid tank 31, a processing fluid transfer outer tube 32, a processing fluid transfer inner tube 35, a pump 33, and a valve 34.

The processing fluid tank 31 may be a tank in which the processing fluid is accommodated and may be provided outside the fluid spray device 20 for processing a substrate. The processing fluid transfer outer tube 32 guides the processing fluid to be transferred from the processing fluid tank 31 to the swing arm support post 21. The processing fluid transfer inner tube 35 extends in the inner space of the swing arm support post 21 and the inner space of the swing arm 25 and extends to pass through the connection through-hole 27 of the first arm housing member 26. One end portion of the processing fluid transfer inner tube 35 is connected to the processing fluid transfer outer tube 32, and the other end portion thereof passes through the scattering prevention cover 60 to be connected to a nozzle inner flow path 51 of the spray nozzle 50. The pump 33 pressurizes the processing fluid such that the processing fluid flows from the processing fluid tank 31 to the nozzle inner flow path 51 of the spray nozzle 50 to be sprayed from a lower end of the spray nozzle 50. The valve 34 allows the processing fluid to selectively flow or stop.

The processing fluid may be a cleaning solution for cleaning the upper surface of the substrate 1. Specifically, the cleaning solution may be deionized water. However, the processing fluid may be a surface protection solution for preventing corrosion or damage, a masking agent for forming a photolithography mask, or the like. Furthermore, the processing fluid is not limited to a liquid and may be a gas. Although only one spray nozzle 50 is provided in the embodiment of the present invention shown in FIG. 2, the present invention is not limited thereto, and a plurality of spray nozzles and a plurality of processing fluid supply units corresponding to the plurality of spray nozzles may be provided to spray a plurality of types of processing fluids. Alternatively, one spray nozzle may also be configured to spray a plurality of types of processing fluids.

The scattering prevention cover 60 is for blocking contaminants that are sprayed from the lower end of the spray nozzle 50 and hit the substrate 1 and bounce to be scattered. The scattering prevention cover 60 includes an outer wall 61, an inner wall 63, a lower wall 68, a first upper wall 70, and a second upper wall 73. The outer wall 61 is disposed to not face the spray nozzle 50, the inner wall 63 is disposed to face the spray nozzle 50, and the lower wall 68 connects a lower end of the inner wall 63 and a lower end of the outer wall 61. The inner wall 63 and the outer wall 61 surround the spray nozzle 50 and extend downward.

The first upper wall 70 and the second upper wall 73 are horizontal plate-shaped portions, and the second upper wall 73 is disposed above the first upper wall 70 to be spaced apart from the first upper wall 70. The first upper wall 70 is connected to an upper end of the inner wall 63, and the second upper wall 73 is connected to an upper end of the outer wall 61. The spray nozzle 50 may be fixedly supported on the first upper wall 70. A cover inner space 75, which is formed to allow gas to flow inside the scattering prevention cover 60, is defined by the outer wall 61, the inner wall 63, the lower wall 68, the first upper wall 70, and the second upper wall 73.

The gas supply unit 40 supplies a gas with high pressure higher than atmospheric pressure to the cover inner space 75. The gas supply unit 40 may include a gas tank 41, a gas transfer outer tube 42, a gas transfer inner tube 45, a gas pump 43, and a valve 44. The gas tank 41 may be a tank in which the gas supplied to cover inner space 75 is accommodated and may be provided outside the fluid spray device 20 for processing a substrate. The gas transfer outer tube 42 guides the gas to be transferred from the gas tank 41 to the swing arm support post 21. In the gas transfer inner tube 45, one end portion thereof is connected to the gas transfer outer tube 42, and the other end portion thereof passes through the second upper wall 73 and extends to the cover inner space 75. The gas transfer inner tube 45 passes through the connection through-hole 27 of the first arm housing member 26 and extends in the inner space of the swing arm support post 21 and the inner space of the swing arm 25.

A plurality of ventilation holes 65 are formed to pass through each of the inner wall 63, the lower wall 68, and the first upper wall 70 in a thickness direction. The plurality of ventilation holes 65 are uniformly distributed over entire areas of the inner wall 63, the lower wall 68, and the first upper wall 70. Accordingly, when the gas with high pressure is supplied to the cover inner space 75, the gas with high pressure passes through the plurality of ventilation holes 65 to be discharged to the outside from the cover inner space 75. In other words, air with high pressure passes through the inner wall 63, the lower wall 68, and the first upper wall 70 to be discharged to the outside from the cover inner space 75.

The gas pump 43 pressurizes the gas at higher pressure than atmospheric pressure such that the gas passes through the cover inner space 75 and passes through the inner wall 63, the lower wall 68, and the first upper wall 70 through the plurality of ventilation holes 65 to be discharged to the outside of the scattering prevention cover 60. The valve 44 allows the gas to selectively flow or stop.

When the processing fluid is sprayed from the spray nozzle 50 of the fluid spray device 20 for processing a substrate onto the substrate 1 supported on the table 13, the gas with high pressure is supplied to the cover inner space 75 through the gas supply unit 40, and the gas with high pressure passes through the plurality of ventilation holes 65 of the inner wall 63, the lower wall 68, and the first upper wall 70 to be discharged to the outside from the cover inner space 75. Accordingly, foreign materials on the substrate 1 and the processing fluid sprayed onto the substrate 1 are mixed, and contaminants which bounce off the substrate 1 are not attached to the inner wall 63, the lower wall 68, and the first upper wall 70 of the scattering prevention cover 60. Considering an angle at which the contaminants bounce, it is difficult for the contaminants to be attached to the outer wall 61 and the second upper wall 73. Therefore, defects of a substrate processing operation are prevented from being caused by contaminants attached to the scattering prevention cover 60 falling on another substrate 1 in a subsequence operation of processing another substrate 1, and since the scattering prevention cover 60 does not need to be separately cleaned, the productivity of the substrate processing operation is improved.

Contaminants not attached to the inner wall 63, the lower wall 68, and the first upper wall 70 may fall on the upper surface of the substrate 1 due to a weight thereof and pressure of a gas spouting through the ventilation holes 65. During a substrate processing operation, the substrate 1 is supported on the chuck table 13 and is rotated about the table axis WR, and the processing fluid is also continuously sprayed onto the substrate 1 so that contaminants falling on the upper surface of the substrate 1 are not attached to the upper surface of the substrate 1 and are removed from the upper surface of the substrate 1 by a centrifugal force.

For example, the gas with high pressure supplied to the cover inner space 75 may be nitrogen gas (N₂) which is less reactive and stable but is not limited thereto. For example, the gas with high pressure may be air from which foreign materials such as dust are filtered. In the fluid spray device 20 for processing a substrate, in a state in which the swing arm 25 pivots about the arm axis AS so that the spray nozzle 50 is positioned above the substrate 1, when the processing fluid is sprayed onto the substrate 1 from the spray nozzle 50, the gas with high pressure passes through the ventilation holes 65 of the inner wall 63, the lower wall 68, and the first upper wall 70 of the scattering prevention cover 60 to be discharged from the cover inner space 75 into the outside of the scattering prevention cover 60.

A lower end of the scattering prevention cover 60, specifically, the lower wall 68, is closer to the upper surface of the substrate 1 than the lower end of the spray nozzle 50. When the spray nozzle 50 is positioned above the substrate 1 and the processing fluid is sprayed onto the substrate 1 from the spray nozzle 50, a separation distance DS between the lower end of the scattering prevention cover 60 and the upper surface of the substrate 1 is in a range of 0.5 mm to 100 mm. When the distance DS is less than 0.5 mm, the lower end of the scattering prevention cover 60 may collide with the substrate 1 due to an unintentional external force or vibration during a processing fluid spray operation through the spray nozzle 50. On the contrary, when the distance DS is greater than 100 mm, contaminants that randomly bounce off the substrate 1 may not be blocked by the scattering prevention cover 60 and may escape through a gap between the lower end of the scattering prevention cover 60 and the upper surface of the substrate 1 to be irregularly scattered far away.

The outer wall 61, the inner wall 63, the lower wall 68, the first upper wall 70, and the second upper wall 73 may each be formed as a separate member to be fixedly coupled to each other through fasteners such as bolts or may be integrally and inseparably formed. Alternatively, the inner wall 63, the lower wall 68, and the first upper wall 70 having the ventilation holes 65 formed therein, as one member, and the outer wall 61 and the second upper wall 73, as another member, may be separably formed.

Meanwhile, the present invention is not limited to the embodiment in which the ventilation holes 65 are formed in the inner wall 63, the lower wall 68, and the first upper wall 70. For example, in the present invention, the ventilation holes 65 are formed, but instead of the inner wall 63, the lower wall 68, and the first upper wall 70, the scattering prevention cover 60 of the present invention may include an inner wall, a lower wall, and a first upper wall made of a porous material in which a plurality of micropores are formed. The porous material may be a foamed resin in which a plurality of micropores are formed. The gas with high pressure introduced into the cover inner space may be discharged to the outside of the scattering prevention cover through the plurality of micropores of the inner wall, the lower wall, and the first upper wall which are made of the porous material.

The cover holder 16 is installed outside the table 13 at a home position at which the spray nozzle 50 and the scattering prevention cover 60 do not overlap the table 13. When the substrate processing apparatus 10 is not operating, the scattering prevention cover 60 is mounted on the cover holder 16. Alternatively, while an operation of processing one substrate 1 is finished and a new substrate 1 replaces the one substrate 1 and is mounted on the table 13, the swing arm 25 rotates clockwise about the arm axis AS so that the scattering prevention cover 60 may be temporarily supported on the cover holder 16.

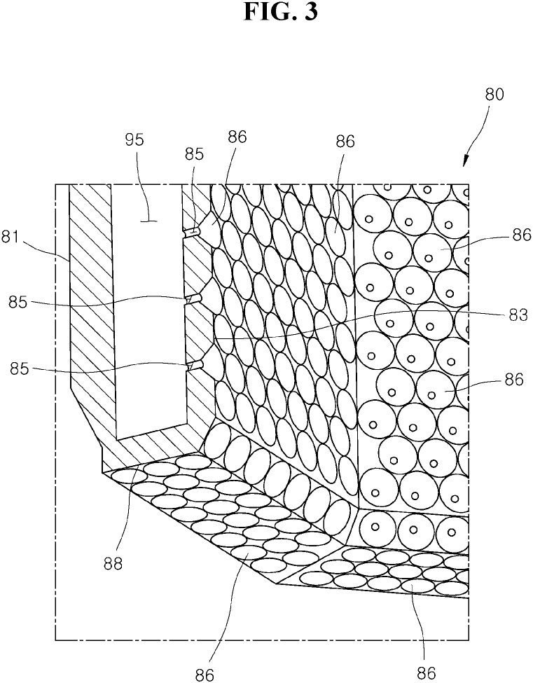

FIG. 3 is a partially cutaway perspective view illustrating a portion of a scattering prevention cover according to a modified example replacing the scattering prevention cover of FIG. 2. A scattering prevention cover 80 shown in FIG. 3 is for blocking contaminants that are sprayed from a lower end of a spray nozzle 50 and hit a substrate 1 and bounce to be scattered. Like the scattering prevention cover 60 shown in FIG. 2, the scattering prevention cover 80 includes an outer wall 81, an inner wall 83, a lower wall 88, a first upper wall (not shown), and a second upper wall (not shown). The outer wall 81 is disposed to not face the spray nozzle 50, the inner wall 83 is disposed to face the spray nozzle 50 (see FIG. 2), and the lower wall 88 connects a lower end of the inner wall 83 and a lower end of the outer wall 81. The inner wall 83 and the outer wall 81 surround the spray nozzle 50 (see FIG. 2) and extend downward. A cover inner space 95, which is formed to allow gas to flow inside the scattering prevention cover 80, may be defined by the outer wall 81, the inner wall 83, the lower wall 88, the first upper wall (not shown), and the second upper wall (not shown).

A plurality of ventilation holes 85 are formed in the inner wall 83, the lower wall 88, and the first upper wall (not shown) to pass through the walls in a thickness direction. The plurality of ventilation holes 85 may be uniformly distributed over an entire area of the inner wall 83, the lower wall 88, and the first upper wall (not shown). Each of the ventilation holes 85 has a diffusion surface 86 of which a size of an inner diameter increases in a direction away from the cover inner space 95. Accordingly, an inner peripheral surface of the ventilation hole 85 may have the same shape as an inner surface of a funnel.

Accordingly, when a gas with high pressure is supplied to the cover inner space 95, the gas with high pressure passes through the plurality of ventilation holes 85 to be discharged from the cover inner space 95 to the outside of the scattering prevention cover 80. In this case, since the gas with high pressure is diffused and discharged through the diffusion surface 86, the gas with high pressure may fully spout from entire areas of side surfaces, from which a gas spouts, of the inner wall 83, the lower wall 88, and the first upper wall (not shown).

Since the fluid spray device 20 for processing a substrate described above includes the scattering prevention cover 60 or 80 which surrounds the spray nozzle 50 and blocks contaminants scattered by the processing fluid sprayed onto the substrate 1 from the spray nozzle 50, the contamination, malfunction, or failure of the substrate processing apparatus 10 including the fluid spray device 20 for processing a substrate is prevented, the productivity of a substrate processing operation is improved, and operation costs are reduced.

In addition, since a gas with high pressure spouts from a side surface, with which bounced contaminants collide, of the scattering prevention cover 60 or 80, the contaminants are not attached to the scattering prevention cover 60 or 80. Therefore, defects of a substrate processing operation are prevented from being caused by contaminants attached to the scattering prevention cover 60 or 80 falling on another substrate 1 in a subsequence operation of processing another substrate 1, and since the scattering prevention cover 60 or 80 does not need to be separately cleaned, the productivity of the substrate processing operation is further improved.

Since a fluid spray device for processing a substrate according to the present invention includes a scattering prevention cover which surrounds a spray nozzle and blocks contaminants scattered by a processing fluid sprayed onto a substrate from the spray nozzle, the contamination, malfunction, or failure of a substrate processing apparatus including the fluid spray device for processing a substrate is prevented, the productivity of a substrate processing operation is improved, and operation costs are reduced.

In addition, according to the present invention, since a gas with high pressure spouts from a side surface, with which bounced contaminants collide, of the scattering prevention cover, the contaminants are not attached to the scattering prevention cover. Therefore, defects of a substrate processing operation are prevented from being caused by contaminants attached to the scattering prevention cover falling on another substrate in a subsequence operation, and since the scattering prevention cover does not need to be separately cleaned, the productivity of the substrate processing operation is further improved.

While the present invention has been described with reference to embodiments shown in the drawings, these should be considered in a descriptive sense only, and it will be understood by those skilled in the art that various alterations and other equivalent embodiments may be made. Accordingly, the true scope of protection of the present invention should be defined only by the appended claims.

What is claimed is:

1. A fluid spray device for processing a substrate, comprising:
a spray nozzle configured to spray a processing fluid toward a substrate supported on a table; and
a scattering prevention cover configured to block contaminants from being scattered by the sprayed processing fluid hitting the substrate.

2. The fluid spray device of claim 1, wherein the scattering prevention cover includes:
an inner wall disposed to face the spray nozzle; and
an outer wall disposed further apart from the spray nozzle than the inner wall.

3. The fluid spray device of claim 2, wherein the scattering prevention cover has a cover inner space which is formed to allow gas to flow between the inner wall and the outer wall.

4. The fluid spray device of claim 3, further comprising a gas supply unit configured to supply a gas with high pressure higher than atmospheric pressure to the cover inner space,
wherein the gas with high pressure passes through the inner wall to be discharged outward from the cover inner space.

5. The fluid spray device of claim 4, wherein a plurality of ventilation holes are formed in the inner wall.

6. The fluid spray device of claim 4, wherein the inner wall is made of a porous material in which a plurality of micropores are formed.

7. The fluid spray device of claim 3, further comprising a gas supply unit configured to supply a gas with high pressure higher than atmospheric pressure to the cover inner space,
wherein the scattering prevention cover further includes a lower wall configured to connect a lower end of the inner wall and a lower end of the outer wall.

8. The fluid spray device of claim 7, wherein the gas with high pressure supplied to the cover inner space through the gas supply unit passes through the lower wall to be discharged outward from the cover inner space.

9. The fluid spray device of claim 8, wherein a plurality of ventilation holes are formed in the outer wall.

10. The fluid spray device of claim 8, wherein the outer wall is made of a porous material in which a plurality of micropores are formed.

11. The fluid spray device of claim 3, further comprising a gas supply unit configured to supply a gas with high pressure higher than atmospheric pressure to the cover inner space,
wherein:
the scattering prevention cover further includes a first upper wall connected to an upper end of the inner wall and a second upper wall connected to an upper end of the outer wall; and
the cover inner space extends to allow gas to flow between the first upper wall and the second upper wall.

12. The fluid spray device of claim 11, wherein the gas with high pressure supplied to the cover inner space through the gas supply unit passes through the first upper wall to be discharged outward from the cover inner space.

13. The fluid spray device of claim 12, wherein a plurality of ventilation holes are formed in the first upper wall.

14. The fluid spray device of claim 12, wherein the first upper wall is made of a porous material in which a plurality of micropores are formed.

15. The fluid spray device of claim 1, wherein:
a lower end of the scattering prevention cover is closer to an upper surface of the substrate than a lower end of the spray nozzle; and
when the processing fluid is sprayed onto the substrate from the spray nozzle, a separation distance between the lower end of the scattering prevention cover and the upper surface of the substrate is in a range of 0.5 mm to 100 mm.
